(19) United States
(12) Patent Application Publication
(10) Pub. No.: US 2024/0014780 A1
(43) Pub. Date: Jan. 11, 2024

(54) AMPLIFIER

(71) Applicant: REALTEK SEMICONDUCTOR CORPORATION, HSINCHU (TW)

(72) Inventor: SHIH-HSIUNG HUANG, HSINCHU COUNTY (TW)

(21) Appl. No.: 18/333,234

(22) Filed: Jun. 12, 2023

(30) Foreign Application Priority Data
Jul. 6, 2022 (TW) 111125400

(51) Int. Cl. H03F 1/02; H03F 3/45

(52) U.S. Cl. CPC H03F 1/0205; H03F 3/45466

(57) ABSTRACT

An amplifier includes a first stage of amplification circuit and a second stage of amplification circuit. The first stage of amplification circuit includes a first transistor, a second transistor, and a voltage gap generation unit. The first transistor has a first terminal, a second terminal for outputting an amplified signal, and a control terminal for receiving an input signal. The second transistor has a first terminal, a second terminal, and a control terminal for receiving a bias voltage. The voltage gap generation unit provides a voltage gap between a first terminal and a second terminal of the voltage gap generation unit according to a current flowing through the first transistor and the second transistor. The second stage of amplification circuit uses the voltages at the first terminal and the second terminal of the voltage gap generation unit as input signals.

### CROSS-REFERENCE TO RELATED APPLICATIONS

This application claims priority of Taiwan application No. 111125400, filed on Jul. 6, 2022, which is incorporated by reference in its entirety.

### TECHNICAL FIELD

The present application relates to a circuit, particularly to an amplification circuit.

### BACKGROUND

For an amplifier containing a two-stage amplification circuit, if the second-stage amplification circuit is composed of stacked transistors, the input voltages of the stacked P-type transistor and N-type transistor may not be designed to be equal in order for the second-stage amplification circuit to have the characteristics of Class AB amplification. In other words, different input voltages are required for the stacked P-type transistor and N-type transistor to ensure proper operation. The common approach is to use an alternating current (AC) coupling capacitor coupled between the gates of the stacked P-type transistor and N-type transistor, but this approach will cause the output signal of the first-stage amplification circuit to degrade during transmission to the second-stage amplification circuit, resulting in poor overall performance of the amplification circuit.

### SUMMARY OF THE INVENTION

One embodiment of the present disclosure provides an amplifier, including a first stage amplification circuit and a second stage amplification circuit. The first stage amplification circuit includes a first transistor, a second transistor and a first voltage gap generation unit. The first transistor has a first terminal, a second terminal and a control terminal, wherein the second terminal of the first transistor is configured to output a first amplified signal, and the control terminal of the first transistor is configured to receive a first input signal. The second transistor has a first terminal, a second terminal and a control terminal, wherein control terminal of the second transistor is configured to receive a first bias voltage. The first voltage gap generation unit is coupled between the second terminal of the first transistor and the second terminal of the second transistor and configured to provide a voltage gap between a first terminal and a second terminal of the first voltage gap generation unit according to a current flowing through the first transistor and of the second transistor. The second stage amplification circuit includes a third transistor and a fourth transistor. The third transistor has a first terminal, a second terminal and a control terminal, wherein the first terminal of the third transistor is configured to receive a first voltage and the second terminal of the third transistor is configured to output a first output signal. The fourth transistor has a first terminal, a second terminal and a control terminal, wherein the first terminal of the fourth transistor is configured to receive a second voltage, and the second terminal of the fourth transistor is coupled to the second terminal of the third transistor. The control terminal of the third transistor and the control terminal of the fourth transistor are coupled to two different terminals of the first voltage gap generation unit.

The amplifier provided in the embodiments of the present disclosure provides a voltage gap at the output terminal of the first-stage amplification circuit using a voltage gap generation unit, so that the stacked transistors in the second stage amplification circuit can receive input signals of different DC levels, thereby improving the performance of the amplifier. In addition, the voltage gap generation unit provides the DC voltage gap through the impedance of a resistor, so the present amplifier can support applications with low frequency input signals compared to amplifiers using AC coupling capacitors in the second stage amplification circuit, and the amplified signal outputted from the first stage amplification circuit is also less likely to degrade when being transmitted to the second stage, thus improving the overall performance of the amplifier.

### BRIEF DESCRIPTION OF THE DRAWINGS

FIG. 1 is a schematic diagram illustrating an amplifier according to one embodiment of the present disclosure.

FIG. 2 is a schematic diagram illustrating voltage gap generation unit according to one embodiment of the present disclosure.

FIG. 3 is a schematic diagram illustrating an amplifier according to another embodiment of the present disclosure.

FIG. 4 is a schematic diagram illustrating an amplifier according to another embodiment of the present disclosure.

FIG. 5 is a schematic diagram illustrating an amplifier according to another embodiment of the present disclosure.

FIG. 6 is a schematic diagram illustrating an amplifier according to another embodiment of the present disclosure.

FIG. 7 is a schematic diagram illustrating an amplifier according to another embodiment of the present disclosure.

FIG. 8 is a schematic diagram illustrating an amplifier according to another embodiment of the present disclosure.

FIG. 9 is a schematic diagram illustrating an amplifier according to another embodiment of the present disclosure.

### DETAILED DESCRIPTION

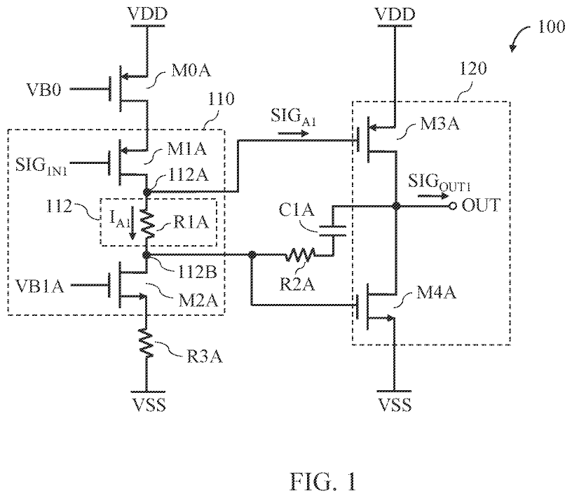

FIG. 1 is a schematic diagram illustrating an amplifier 100 according to a first embodiment of the present disclosure. The amplifier 100 includes a first stage amplification circuit 110 and a second stage amplification circuit 120. The first stage amplification circuit 110 includes transistors M1A, M2A and a voltage gap generation unit 112. The second stage amplification circuit 120 includes transistors M3A and M4A. In the present embodiment, the transistor M1A can amplify and output the input signal SIG_{IN1} of the amplifier 100, the transistor M2A can be used as a load, whereas the voltage gap generation unit 112 can generate a voltage gap between a first terminal 112A and a second terminal 112B thereof according to a current I_{A1} flowing from the first transistor M1A to the second transistor M2A. In such case, the second stage amplification circuit 120 can use the voltages of the first terminal 112A and the voltage of the second terminal 112B of the first voltage gap generation unit 112 as input signals of the second stage amplification circuit 120.

For the ease of understanding the correspondence between the present disclosure and the drawings, in the present disclosure, the first terminal of each transistor can correspond to the source of each transistor, second terminal of each transistor can respectively correspond to the drain of each transistor in the drawings, and the control terminal of each transistor can correspond to the gate each transistor in the drawings; however, the present disclosure is not limited thereto. As shown in FIG. 1, the transistor M1A has a first terminal, a second terminal and a control terminal, wherein the first terminal of the transistor M1A is coupled to the transistor MOA to receive a supply voltage VDD, the second terminal of the transistor M1A is coupled to the first terminal 112A of the first voltage gap generation unit 112 to output an amplified signal SIG_{A1}, and the control terminal of the transistor M1A can receive an input signal SIG_{IN1}. The transistor M2A has a first terminal, a second terminal and a control terminal, wherein the first terminal of the transistor M2A is coupled to the resistor R3A to receive a ground voltage VSS, the second terminal of the transistor M2A is coupled to the second terminal 112B of the first voltage gap generation unit 112, and the control terminal of the transistor M2A can receive a bias voltage VB1A. The transistor MOA has a first terminal, a second terminal and a control terminal, wherein the first terminal of the transistor MOA is coupled to the supply voltage VDD, the second terminal of the transistor MOA is coupled to the first terminal of the transistor M1A, and the control terminal of the transistor MOA can receive the bias voltage VB0. However, the present disclosure is not limited thereto, in some embodiments, the amplifier 100 may omit the transistor MOA, so that the first terminal of the transistor M1A can be directly coupled to the supply voltage VDD; alternatively, the amplifier 100 can also omit the resistor R3A, so that the first terminal of the transistor M2A can be directly coupled to the ground voltage VSS.

In the present embodiment, the transistor M1A can be a P-type transistor, and the transistor M2A can be an N-type transistor.

Furthermore, the transistor M3A has a first terminal, a second terminal and a control terminal, wherein the first terminal of the transistor M3A can receive a first voltage, and the second terminal of the transistor M3A can be used as an output terminal OUT of the amplifier 100, and. can output the output signal SIG_{OUT1}. The transistor M4A has a first terminal, a second terminal and a control terminal, wherein the first terminal of the transistor M4A can receive a second voltage, and the second terminal of the transistor M4A can be coupled to the second terminal of the transistor M3A. In some embodiments, the first voltage can be, for example, the supply voltage VDD of the system, whereas the second voltage can be, for example, the ground voltage (or reference voltage) VSS of the system.

In the present embodiment, the transistor M3A can be a P-type transistor, whereas the transistor M4A can be an N-type transistor. Furthermore, as shown in FIG. 1, the voltage gap generation unit 112 can include, for example, a resistor R1A. In such case, the current I_{A} generated by the transistor M1A according to the input signal SIG_{IN1} will flow through the resistor R1A and create a voltage gap between the two terminals of the resistor R1A, and the control terminal of the transistor M3A and the control terminal of the transistor M4A can be respectively coupled to the two terminals of the resistor R1A, i.e., the two terminals of the voltage gap generation unit 112. For example, the control terminal of the transistor M3A can be coupled to the first terminal 112A of the voltage gap generation unit 112, and the control terminal of the transistor M4A can be coupled to the second terminal 112B of the voltage gap generation unit 112.

Since the voltages at the two terminals of the voltage gap generation unit 112 are related to the amplified signal SIG_{A1} generate d by the transistor M1A, both the transistor M3A and the transistor M4A of the second stage amplification circuit 120 can amplify the signal. For example, the transistor M3A and the transistor M4A can respectively generate a charge current and a discharge current to the output terminal OUT. When the voltage of the amplified signal SIG_{A1} increases, the current I_{A1} also increases, and the voltages at the two terminals of the voltage gap generation unit 112 both increase; in such case, the charge current generated by the transistor M3A is smaller, whereas the transistor M4A provides a larger discharge current to the output terminal OUT, thereby pulling down the voltage of the output signal SIG_{OUT1}. On the contrary, when the voltage of the amplified signal SIG_{A1} decreases, the current I_{A1} also decreases, and the voltages of the two terminals of the voltage gap generation unit 112 both decrease; in such case, the transistor M3A provides a larger charge current to the output terminal OUT, whereas the discharge current generated by the transistor M4A decreases, thereby pulling up the voltage of the output signal SIG_{OUT1}. That is, in the present embodiment, the second stage amplification circuit 120 can be used as a Class AB output stage.

In the conventional technology, the second stage amplification circuit often receives the input signals through an AC coupling capacitor; however, because the gate of the transistor in the second stage amplification circuit has a parasitic capacitance, the voltage of the input signals that the second stage amplification circuit actually received are the result of voltage division between the AC coupling capacitor and the parasitic capacitance. In such case, if the capacitance of the coupling capacitor is not large enough, the input signals of the second stage amplification circuit may degrade severely, resulting in poor performance of the amplifier, while using a coupling capacitor with a larger capacitance will significantly increase the required area of the circuit. Furthermore, since the coupling capacitor blocks low-frequency signals, it cannot support applications where the input signal is low-frequency, for example, it cannot be used as an audio amplifier.

In contrast, in the present embodiment, the first stage amplification circuit 110 can generate signals with different DC voltages through the voltage gap generation unit 112 as two input signals of the second stage amplification circuit 120, thus reducing the issue of signal degradation and requiring a smaller circuit areas. Further, since the voltage gap generation unit 112 generates the voltage gap according to the resistor characteristic and does not use capacitive component that blocks low frequency signals, the amplifier 100 can also support applications where the input signal is low frequency.

Furthermore, as shown in FIG. 1, the amplifier 100 can further include a resistor R2A and a capacitor C1A serially connected between the second terminal 112B of the voltage gap generation unit 112 and the second terminal of the transistor M3A. The capacitor C1A can be configured to compensate the Miller effect of the amplifier 100. However, the present disclosure is not limited thereto, and in some other embodiments, the amplifier 100 can also omit the resistor R2A and the capacitor CIA.

In the embodiment of FIG. 1, the voltage gap generation unit 112 can generate the voltage gap at the two terminals of the resistor R1A when the current I_{A} flows through the resistor R1A; however, the present disclosure is not limited thereto. In some embodiments, the voltage gap generation unit 112 can also use the transistor as the DC impedance to generate the voltage gap at the two terminals of the voltage gap generation unit 112.

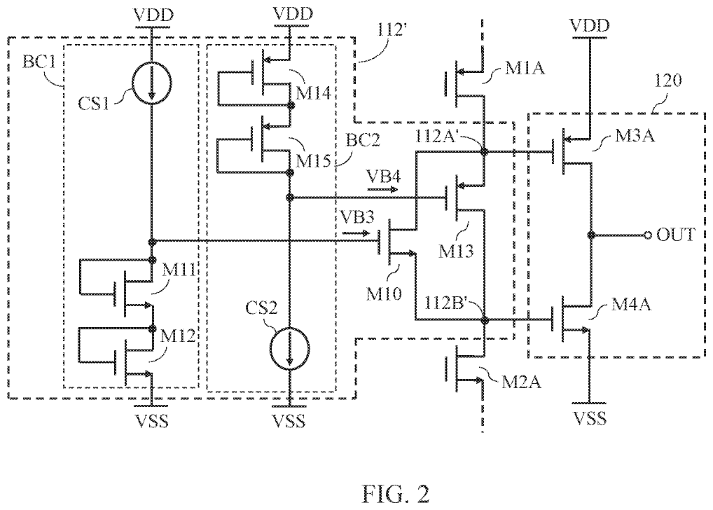

FIG. 2 is a schematic diagram illustrating a voltage gap generation unit 112′ according to one embodiment of the present disclosure. As shown in FIG. 2, the voltage gap generation unit 112′ can include a transistor M10, a transistor M13, a bias voltage circuit BC1 and a bias voltage circuit BC2. In the present embodiment, the transistor M10 can be an N-type transistor, whereas the transistor M13 can be a P-type transistor.

The transistor M10 has a first terminal coupled to the second terminal 112B′ of the voltage gap generation unit 112′, the second terminal of the transistor M10 is coupled to the first terminal 112A′ of the voltage gap generation unit 112′, and the control terminal of the transistor M10 can receive the bias voltage VB3. The bias voltage circuit BC1 can include a transistor M11, a transistor M12 and a current source CS1. The transistor M11 has a first terminal, a second terminal and a control terminal, wherein the second terminal of the transistor M11 can be coupled to the current source CS1, and the control terminal of the transistor M11 can be coupled to the first terminal of the transistor M11. The transistor M12 has a first terminal, a second terminal and a control terminal, wherein the second terminal of the transistor M12 can be coupled to the first terminal of the transistor M11, the first terminal of the transistor M12 can receive the ground voltage VSS, and the control terminal can be coupled to the first terminal of the transistor M12.

In the foregoing embodiments, the transistor M11 and the transistor M12 are both N-type transistors, and the transistor M11 and the transistor M12 are both connected in the form of equivalent diodes. In such case, by serially connecting the transistor M11 and the transistor M12, it is feasible to output the bias voltage VB3 at the first terminal of the transistor M11 for the transistor M10 to receive. However, the present disclosure is not limited thereto, in some other embodiments, the bias voltage circuit BC1 can also include one or more to transistors coupled in the form of equivalent diodes.

The transistor M13 has a first terminal, a second terminal and a control terminal, wherein the first terminal of the transistor M13 is coupled to the first terminal 112A′ of the voltage gap generation unit 112′, the second terminal of the transistor M13 is coupled to the second terminal 112B′ of the voltage gap generation unit 112′, and the control terminal of the transistor M13 can receive the bias voltage VB4. The bias voltage circuit BC2 can include a transistor M14, a transistor M15 and a current source CS2. The transistor M14 has a first terminal, a second terminal and a control terminal, wherein the first terminal of the transistor M14 can receive the supply voltage VDD, and the control terminal of the transistor M14 can be coupled to the second terminal of the transistor M14. The transistor M15 has a first terminal, a second terminal and a control terminal, wherein the first terminal of the transistor M15 can be coupled to the second terminal of the transistor M14, and the control terminal of the transistor M15 can be coupled to the second terminal of the transistor M15. Furthermore, the current source CS2 can be coupled to the second terminal of the transistor M15.

In the foregoing embodiments, the transistor M14 and the transistor M15 are both connected in the form of equivalent diodes, and the transistor M14 and the transistor M15 are both P-type transistors. In such case, by serially connecting the transistor M14 and the transistor M15, it is feasible to output the bias voltage VB4 at the second terminal of the transistor M15 for the transistor M13 to receive. However, the present disclosure is not limited thereto, in some other embodiments, the bias voltage circuit BC2 can also include one or more to transistors coupled in the form of equivalent diodes.

In some embodiments, the voltage gap generation unit 112′ can replace the voltage gap generation unit 112, and is configured to generate the voltage gap between the second terminal of the transistor M1A and the second terminal of the transistor M2A in the amplifier 100. Since the voltage gap generation unit 112′ can conduct the transistors M10 and M13 with the bias voltages VB3 and VB4 and can provide a lower DC impedance through the transistor M10 and M13, the effect of the voltage gap generation unit 112′ on the amplification performance can be reduced.

In the present embodiment, the voltage gap generation unit 112′ provides DC impedance through the transistor M10 and M13; however, the present disclosure is not limited thereto. In some embodiments, the voltage gap generation unit 112′ can also omit the transistor M10 and the bias voltage circuit BC1 or omit the transistor M13 and the bias voltage circuit BC2.

Furthermore, in the embodiment of FIG. 1, the first terminal 112A of the voltage gap generation unit 112 is coupled to the second terminal of the transistor M1A, and the second terminal 112B of the voltage gap generation unit 112 is coupled to the second terminal of the transistor M2A. However, the present disclosure is not limited thereto.

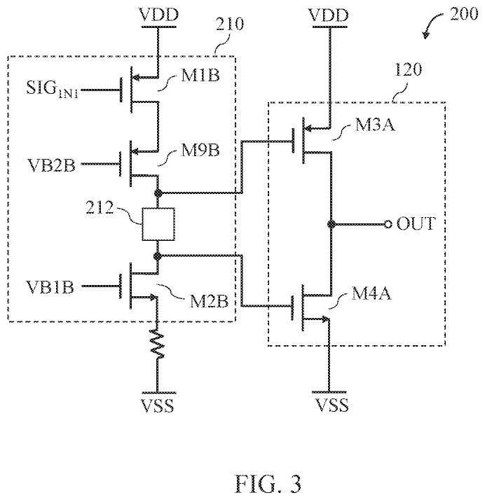

FIG. 3 is a schematic diagram illustrating an amplifier 200 according to another embodiment of the present disclosure. The first stage amplification circuit 210 of the amplifier 200 can include a transistor M1B, a transistor M2B, a transistor M9B and a voltage gap generation unit 212.

In the present embodiment, the transistor M9B has a first terminal, a second terminal and a control terminal, wherein the first terminal of the transistor M9B is coupled to the second terminal of the transistor M1B, the second terminal of the transistor M9B can be coupled to the first terminal of the voltage gap generation unit 212, and the control terminal of the transistor M9B can receive a bias voltage VB2B. The control terminal of the transistor M2B can receive a bias voltage VB1B. In such case, the transistor M9B and the transistor M2B can both be used as load transistors in the first stage amplification circuit 210.

Furthermore, the transistor M9B and the transistor M1B can be, for example, transistors of the same type, e.g., both are P-type transistors, but the present disclosure is not limited thereto. Moreover, the structure of the voltage gap generation unit 212 can be, for example, the same as that of the voltage gap generation unit 112 or the voltage gap generation unit 112′, and the second terminal of the voltage gap generation unit 212 can be coupled to the second terminal of the transistor M2B.

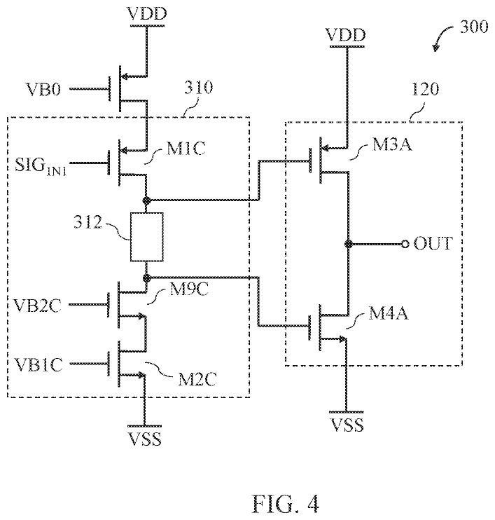

FIG. 4 is a schematic diagram illustrating an amplifier 300 according to another embodiment of the present disclosure. The first stage amplification circuit 310 of the amplifier 300 can include a transistor M1C, a transistor M2C, a transistor M9C and a voltage gap generation unit 312.

In the present embodiment, the transistor M9C has a first terminal, a second terminal and a control terminal, wherein the first terminal of the transistor M9C can be coupled to the second terminal of the transistor M2C, the second terminal of the transistor M9C can be coupled to the second terminal of the voltage gap generation unit 312, and the control terminal of the transistor M9C can receive bias voltage VB2C. The control terminal of the transistor M2C can receive a bias voltage VB1C. In such case, the transistor M9C and the transistor M2C can both be used as load transistors in the first stage amplification circuit 210.

Furthermore, the transistor M9C and the transistor M2C can be, for example, transistors of the same type, e.g., both are N-type transistors, but the present disclosure is not limited thereto. Moreover, the structure of the voltage gap generation unit 312 can be, for example, the same as that of the voltage gap generation unit 112 or the voltage gap generation unit 112′, and the first terminal of the voltage gap generation unit 312 can be coupled to the second terminal of the transistor M1C.

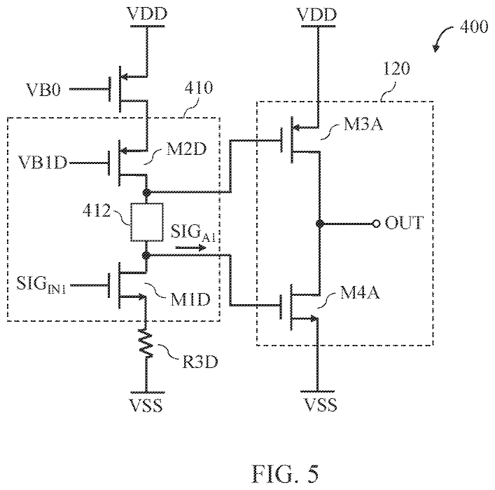

In the embodiments of FIG. 1, FIG. 3 and FIG. 4, the transistors M1A, M1B and M1C of the amplifiers 100, 200 and 300 that are configured to receive the input signal SIG_{IN1} are all P-type transistors; however, the present disclosure is not limited thereto. FIG. 5 is a schematic diagram illustrating an amplifier 400 according to another embodiment of the present disclosure. In the embodiment of FIG. 5, the first stage amplification circuit 410 can use the N-type transistor M1D to receive the input signal SIG_{IN1}, and the control terminal of the P-type transistor M2D can receive the bias voltage VB1D and can be used as a load transistor.

Similar to the amplifier 100, the transistor M1D has a first terminal, a second terminal and a control terminal, wherein the second terminal of the transistor M1D can output the amplified signal SIG_{A1}, and the control terminal of the transistor M1D can receive the input signal SIG_{IN1}. The transistor M2D has a first terminal, a second terminal and a control terminal, wherein the control terminal of the transistor M2D can receive the bias voltage VB1D. In the present embodiment, the transistor M1D can receive the ground voltage VSS through the resistor R3D. Furthermore, the first terminal of the voltage gap generation unit 412 can be coupled to the second terminal of the transistor M1D, and the second terminal of the voltage gap generation unit 412 can be coupled to the second terminal of the transistor M2D.

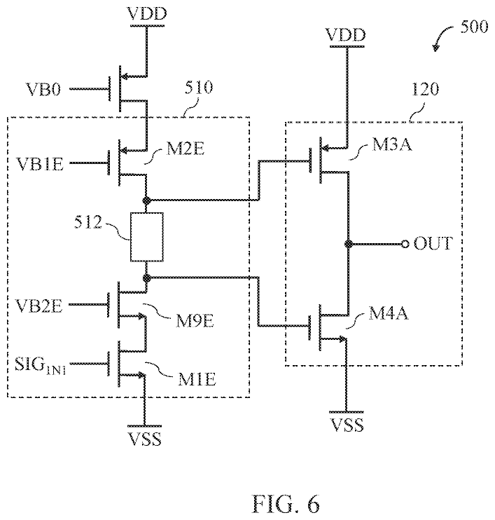

Furthermore, the first stage amplification circuit 410 of the amplifier 400 can also include more load transistors. FIG. 6 is a schematic diagram illustrating an amplifier 500 according to another embodiment of the present disclosure. The first stage amplification circuit 510 of the amplifier 500 can include transistors M1E, M2E and M9E. In the present embodiment, the transistor M9E has a first terminal, a second terminal and a control terminal, wherein the first terminal of the transistor M9E can be coupled to the second terminal of the transistor M1E, the second terminal of the transistor can be coupled to the first terminal of the voltage gap generation unit 512, and the control terminal of the transistor M9E can receive a bias voltage VB2E. The control terminal of the transistor M2E can receive a bias voltage VB1E. In such case, the transistor M9E and the transistor M2E can both be used as load transistors in the first stage amplification circuit 510.

In addition, the transistor M9E and the transistor M1E can be, for example, transistors of the same type, such as both are N-type transistors, but the present disclosure is not limited thereto. Moreover, the structure of the voltage gap generation unit 512 can be, for example, the same as that of the voltage gap generation unit 112 or the voltage gap generation unit 112′, and the first terminal of the voltage gap generation unit 512 can be coupled to the second terminal of the transistor M2E.

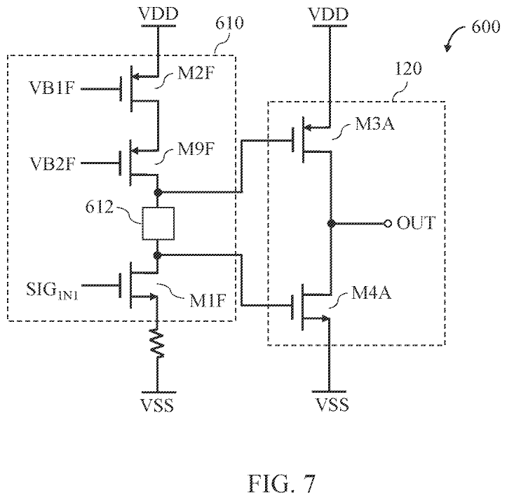

FIG. 7 is a schematic diagram illustrating an amplifier 600 according to another embodiment of the present disclosure. The first stage amplification circuit 610 of the amplifier 600 can include transistors M1F, M2F and M9F. In the present embodiment, the transistor M9F has a first terminal, a second terminal and a control terminal, wherein the first terminal of the transistor M9F can be coupled to the second terminal of the transistor M2F, the second terminal of the transistor M9F can be coupled to the first terminal of the voltage gap generation unit 612, and the control terminal of the transistor M9F can receive a bias voltage VB2F. The control terminal of the transistor M2F can receive a bias voltage VB1F. In such case, the transistor M9F and the transistor M2F can both be used as load transistors in the first stage amplification circuit 610.

Furthermore, the transistor M9F and the transistor M2F can be, for example, transistors of the same type, such as both are P-type transistors, but the present disclosure is not limited thereto. Moreover, the structure of the voltage gap generation unit 612 can be, for example, the same as that of the voltage gap generation unit 112 or the voltage gap generation unit 112′, and the first terminal of the voltage gap generation unit 612 can be coupled to the second terminal of the transistor M1F.

In addition, in the embodiment of FIG. 1, the control terminal of the transistor M3A of the second stage amplification circuit 120 can be coupled to the first terminal 112A of the voltage gap generation unit 112, and the control terminal of the transistor M4A of the second stage amplification circuit 120 can be coupled to the second terminal 112B of the voltage gap generation unit 112; thus, the voltage received at the control terminal of the transistor M3A is greater than the voltage receive at the control terminal of the transistor M4A. However, the present disclosure is not limited thereto. In some embodiments, since the supply voltage VDD is relatively low (e.g., less than 1V), the voltage received by the control terminal of the P-type transistor can be less than the voltage received by the control terminal of the N-type transistor, thereby ensuring the normal operation of the P-type transistor and N-type transistor.

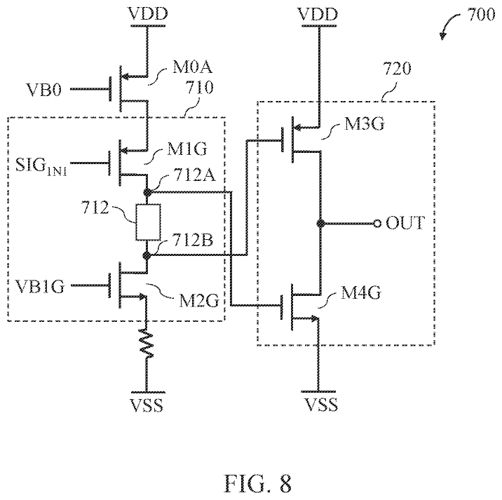

FIG. 8 is a schematic diagram illustrating an amplifier 700 according to another embodiment of the present disclosure. As shown in FIG. 8, the first stage amplification circuit 710 can include a transistor M1G, a transistor M2G and a voltage gap generation unit 712. In the present embodiment, the voltage gap generation unit 712 can be coupled between the P-type transistor M1G and the N-type transistor M2G; therefore, the voltage at the first terminal 712A of the voltage gap generation unit 712 is higher than the voltage at the second terminal 712B of the voltage gap generation unit 712.

Furthermore, since the supply voltage VDD in the present embodiment is relatively low (e.g., less than 1V), the turn-on voltage of the transistor M3G in the second stage amplification circuit 720 is lower than the turn-on voltage of the transistor M4G. In such case, the control terminal of the transistor M3G can be coupled to the second terminal 712B of the voltage gap generation unit 712, and the control terminal of the transistor M4G can be coupled to the first terminal 712A of the voltage gap generation unit 712. Similarly, in some embodiments, the second stage amplification circuits 120 in the amplifiers 200, 300, 400, 500 and 600 can be coupled according to the coupling scheme of the second stage amplification circuit 720, so as to ensure that the P-type transistors and N-type transistors stacked therein can function normally.

In addition, although in the foregoing embodiments, the amplifiers 100, 200, 300, 400, 500, 600 and 700 are amplifiers having a single terminal, the present disclosure is not limited thereto. In other embodiments of the present disclosure, the amplifiers 100, 200, 300, 400, 500, 600 and 700 may also be structured as symmetrical units to implement differential input and differential output amplifiers.

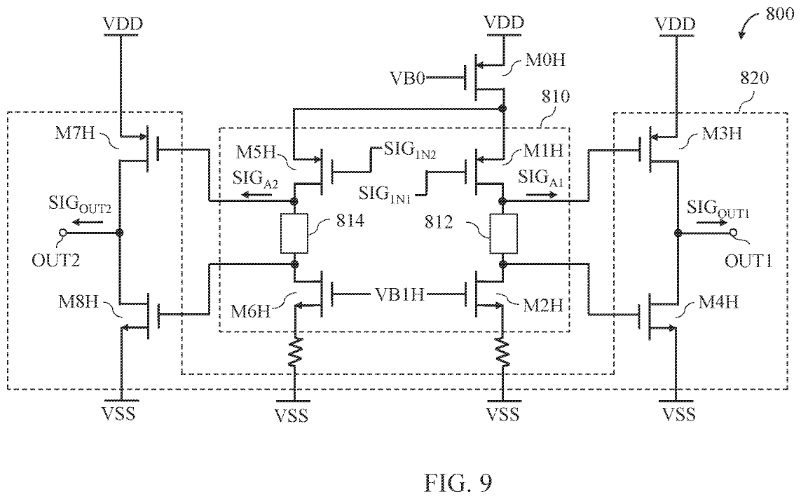

FIG. 9 is a schematic diagram illustrating an amplifier 800 according to another embodiment of the present disclosure. The amplifier 800 is a differential amplifier implemented with the amplifier 100 as a symmetrical unit. The amplifier 800 includes a first stage amplification circuit 810 and a second stage amplification circuit 820.

The first stage amplification circuit 810 includes a transistor M1H, a transistor M2H, a transistor M5H, a transistor M6H, a voltage gap generation unit 812 and a voltage gap generation unit 814. The transistor M1H, the transistor M2H and the voltage gap generation unit 812 are coupled in the same way that the transistor M1A, the transistor M2A and the voltage gap generation unit 112 of FIG. 1 are coupled. For example, the voltage gap generation unit 812 can be coupled between the transistor M1H and the transistor M2H, and the control terminal of the transistor M1H can receive a first input signal SIG_{IN1}, and the second terminal of the transistor M1H can output a first amplified signal SIG_{A1}.

Furthermore, the transistor M5H, the transistor M6H, the voltage gap generation unit 814 are coupled in a similar way that the transistor M1H, the transistor M2H and the voltage gap generation unit 812 are coupled. For example, the transistor M5H has a first terminal, a second terminal and a control terminal, wherein the second terminal of the transistor M5H can output a second amplified signal SIG_{A2}, and the control terminal of the transistor M5H can receive the second input signal SIG_{IN2}, wherein the first input signal SIGIN1 and the second input signal SIGIN2 are a pair of differential signals. The transistor M6H has a first terminal, a second terminal and a control terminal, and the control terminal of the transistor M6H can have receive the same bias voltage VB1H as that received at the control terminal of the transistor M2H. The voltage gap generation unit 814 can be coupled between the second terminal of the transistor M5H and the second terminal of the transistor M6H, and provide a voltage gap between the first terminal and the second terminal of the voltage gap generation unit 814 according to the current flowing through the transistor M5H and the transistor M6H.

In the present embodiment, the control terminal of the transistor M1H and the control terminal of the transistor M5H can be coupled to the supply voltage VDD through the transistor M0H, and the control terminal of the transistor M0H can receive the bias voltage VB0.

Furthermore, the second stage amplification circuit 820 can include a transistor M3H, a transistor M4H, a transistor M7H and a transistor M8H. The transistor M3H and the transistor M4H are coupled in the same way that the transistor M3A and the transistor M4A are coupled. For example, the control terminal of the transistor M3H can be coupled to the first terminal of the voltage gap generation unit 812, and the control terminal of the transistor M4H can be coupled to the second terminal of the voltage gap generation unit 812. In addition, the second terminal of the transistor M3H can be used as the first output terminal OUT1 of the amplifier 800 and can output the first output signal SIG_{OUT1}, and the first terminal of the transistor M4H can be coupled to the second terminal of the transistor M3H.

Furthermore, the transistor M7H, the transistor M8H, the voltage gap generation unit 814 are coupled in a similar way that the transistor M3H, the transistor M4H and the voltage gap generation unit 812 are coupled. For example, the transistor M7H has a first terminal, a second terminal and a control terminal, wherein the first terminal of the transistor M7H can receive a first voltage, such as a supply voltage VDD, and the second terminal of the transistor M7H can be used as the second output terminal OUT2 of the amplifier 800 and can output the second output signal SIG_{OUT2}. The transistor M8H has a first terminal, a second terminal and a control terminal, wherein the first terminal of the transistor M8H can receive a second voltage, such as a ground voltage VSS, and the second terminal of the transistor M8H is coupled to the second terminal of the transistor M7H. In addition, the control terminal of the transistor M7H can be coupled to the first terminal of the voltage gap generation unit 814, and the control terminal of the transistor M8H can be coupled to the second terminal of the voltage gap generation unit 814.

In the present embodiment, the amplifier 800 is a differential amplifier implemented with the amplifier 100 as a symmetrical unit; however, the present disclosure is not limited thereto. In some embodiments, the amplifier according to the present disclosure can also use any of the amplifiers 200 to 700 shown in FIG. 3 to FIG. 8 as the basic unit of a symmetrical structure, thereby implementing a differential amplifier having the two-terminal input and output.

In summary, the amplifier provided by the embodiments of the present disclosure can provide a voltage gap at the output terminal of the first stage amplification circuit by using a voltage gap generation unit, so that the P-type transistor and N-type transistor stacked in the second stage amplification circuit can receive input signals with different DC levels, thereby improving the performance of the amplifier. In addition, since the voltage gap unit provides DC voltage gap with resistive impedance, the amplifier of the present disclosure can support applications with low frequency input signals compared to amplifiers using AC coupling capacitors in the second stage amplifier circuit, and the amplified signal outputted from the first stage amplification circuit is also less likely to degrade when being passed to the second stage, thus improving the overall performance of the amplifier.

What is claimed is:

1. An amplifier, comprising:
a first stage amplification circuit, comprising:
a first transistor, having a first terminal, a second terminal and a control terminal, wherein the second terminal of the first transistor is configured to output a first amplified signal, and the control terminal of the first transistor is configured to receive a first input signal;
a second transistor, having a first terminal, a second terminal and a control terminal, wherein the control terminal of the second transistor is configured to receive a first bias voltage; and
a first voltage gap generation unit, coupled between the second terminal of the first transistor and the second terminal of the second transistor and configured to provide a voltage gap between a first terminal and a second terminal of the first voltage gap generation unit according to a current flowing through the first transistor and the second transistor; and
a second stage amplification circuit, comprising:
a third transistor, having a first terminal, a second terminal and a control terminal, wherein the first terminal of the third transistor is configured to receive a first voltage, and the second terminal of the third transistor is configured to output a first output signal; and
a fourth transistor, having a first terminal, a second terminal and a control terminal, wherein the first terminal of the fourth transistor is configured to receive a second voltage, and the second terminal of the fourth transistor is coupled to the second terminal of the third transistor;
wherein the control terminal of the third transistor and the control terminal of the fourth transistor is coupled between two different terminals of the first voltage gap generation unit.

2. The amplifier of claim 1, wherein the first transistor is a P-type transistor, and the second transistor is a N-type transistor.

3. The amplifier of claim 1, wherein the first transistor is a N-type transistor, and the second transistor is a P-type transistor.

4. The amplifier of claim 1, wherein:
the first terminal the first transistor is a source of the first transistor, the second terminal of the first transistor is a drain of the first transistor, and the control terminal of the first transistor is a gate of the first transistor; and
the first terminal of the second transistor is a source of the second transistor, the second terminal of the second transistor is a drain of the second transistor, and the control terminal of the second transistor is a gate of the second transistor.

5. The amplifier of claim 1, wherein:
the control terminal of the third transistor is coupled to the first terminal of the first voltage gap generation unit, and the control terminal of the fourth transistor is coupled to the second terminal of the first voltage gap generation unit.

6. The amplifier of claim 1, wherein:
the control terminal of the third transistor is coupled to the second terminal of the first voltage gap generation unit, and the control terminal of the fourth transistor is coupled to the first terminal of the first voltage gap generation unit.

7. The amplifier of claim 1, wherein the first stage amplification circuit further comprises:
a fifth transistor, having a first terminal, a second terminal configured to output a second amplified signal, and a control terminal configured to receive a second input signal, wherein the first input signal and the second input signal are a pair of differential signals;
a sixth transistor, having a first terminal, a second terminal, and a control terminal configured to receive the first bias voltage; and
a second voltage gap generation unit, coupled between the second terminal of the fifth transistor and the second terminal of the sixth transistor and configured to provide a voltage gap between a first terminal and a second terminal of the second voltage gap generation unit according to a current flowing through the fifth transistor and the sixth transistor.

8. The amplifier of claim 7, wherein the second stage amplification circuit further comprises:
a seventh transistor, having a first terminal configured to receive the first voltage, a second terminal configured to output a second output signal, and a control terminal;
an eighth transistor, having a first terminal configured to receive the second voltage, a second terminal coupled to the second terminal of the seventh transistor, and a control terminal;
wherein the control terminal of the seventh transistor and the control terminal of the eighth transistor are coupled to two different terminals of the second voltage gap generation unit.

9. The amplifier of claim 7, wherein the third transistor and the seventh transistor are P-type transistors, and the fourth transistor and the eighth transistor are N-type transistors.

10. The amplifier of claim 1, wherein:
the first terminal of the first voltage gap generation unit is coupled to the second terminal of the first transistor, and the second terminal of the first voltage gap generation unit is coupled to the second terminal of the second transistor.

11. The amplifier of claim 1, wherein the first stage amplification circuit further comprises:
a ninth transistor, having a first terminal coupled to the second terminal of the first transistor, a second terminal coupled to the first terminal of the first voltage gap generation unit, and a control terminal configured to receive a second bias voltage;
wherein the second terminal of the first voltage gap generation unit is coupled to the second terminal of the second transistor.

12. The amplifier of claim 11, wherein the ninth transistor and the first transistor are transistors of the same type.

13. The amplifier of claim 1, wherein the first stage amplification circuit further comprises:
a ninth transistor, having a first terminal coupled to the second terminal of the second transistor, a second terminal coupled to the second terminal of the first voltage gap generation unit, and a control terminal configured to receive a second bias voltage;
wherein the first terminal of the first voltage gap generation unit is coupled to the second terminal of the first transistor.

14. The amplifier of claim 13, wherein the ninth transistor and the second transistor are transistors of the same type.

15. The amplifier of claim 1, wherein the first voltage gap generation unit comprises a resistor.

16. The amplifier of claim 1, wherein the first voltage gap generation unit comprises a tenth transistor, having a first terminal coupled to the second terminal of the first voltage gap generation unit, a second terminal coupled to the first terminal of the first voltage gap generation unit, and a control terminal configured to receive a third bias voltage.

17. The amplifier of claim 16, wherein the tenth transistor is an N-type transistor, and first voltage gap generation unit further comprises a first bias voltage circuit, comprising:
a first current source;
an eleventh transistor, having a first terminal, a second terminal coupled to the first current source and configured to output the third bias voltage, and a control terminal coupled to the first terminal of the eleventh transistor; and
a twelfth transistor, having a first terminal configured to receive a ground voltage, a second terminal coupled to the first terminal of the eleventh transistor, and a control terminal coupled to the first terminal of the twelfth transistor;
wherein the eleventh transistor and the twelfth transistor are N-type transistors.

18. The amplifier of claim 16, wherein the first voltage gap generation unit further comprises a thirteenth transistor, having a first terminal coupled to the first terminal of the first voltage gap generation unit, a second terminal coupled to the second terminal of the first voltage gap generation unit, and a control terminal configured to receive a fourth bias voltage, wherein one of the tenth transistor and the thirteenth transistor is an N-type transistor and the other is a P-type transistor.

19. The amplifier of claim 18, wherein the thirteenth transistor is a P-type transistor, and the first voltage gap generation unit further comprises a second bias voltage circuit, comprising:
a fourteenth transistor, having a first terminal coupled to a supply voltage, a second terminal, and a control terminal coupled to the first terminal of the fourteenth transistor;
a fifteenth transistor, having a first terminal coupled to the second terminal of the fourteenth transistor, a second terminal configured to output the fourth bias voltage, and a control terminal coupled to the first terminal of the fifteenth transistor; and
a second current source, coupled to the second terminal of the fifteenth transistor;
wherein the fourteenth transistor and the fifteenth transistor are P-type transistors.

20. The amplifier of claim 1, further comprising a resistor and a capacitor serially connected between the second terminal of the first voltage gap generation unit and the second terminal of the third transistor.
